(19) United States
(12) Patent Application Publication
(10) Pub. No.: US 2013/0029488 A1
(43) Pub. Date: Jan. 31, 2013

(54) Single Liner Process to Achieve Dual Stress

(71) Applicants: Ming Cai, Hopewell Junction, NY (US); Dechao Guo, Fishkill, NY (US); Chun-chen Yeh, Clifton Park, NY (US)

(72) Inventors: Ming Cai, Hopewell Junction, NY (US); Dechao Guo, Fishkill, NY (US); Chun-chen Yeh, Clifton Park, NY (US)

(73) Assignee: INTERNATIONAL BUSINESS MACHINES CORPORATION, Armonk, NY (US)

(21) Appl. No.: 13/192,744

(22) Filed: Jul. 28, 2011

(51) Int. Cl. H01L 21/3205

(52) U.S. Cl. 438/669; 257/E21.295

(57) ABSTRACT

Methods for imparting a dual stress property in a stress liner layer of a semiconductor device. The methods include depositing a metal layer over a compressive stress liner layer, applying a masking agent to a portion of the metal layer to produce a masked and unmasked region of the metal layer, etching the unmasked region of the metal layer to remove the metal layer in the unmasked region to thereby expose a corresponding portion of the compressive stress liner layer, removing the mask to expose the metal layer from the masked region, and irradiating the compressive stress liner layer to impart a tensile stress property to the exposed portion of the compressive stress liner layer. Methods are also provided for imparting a compressive-neutral dual stress property in a stress liner layer, as well as for imparting a neutral-tensile dual stress property in a stress liner layer.

### FIELD OF THE INVENTION

Embodiments of the invention generally relate to electronic devices and, more particularly, to field-effect transistor (FET) devices.

### BACKGROUND OF THE INVENTION

Silicide resistance in the active region, especially for PFET with eSiGe, can be severely degraded by the dual stress liner (DSL) process. This can be caused by the tensile nitride reactive-ion etching (RIE) process on PFET, which is needed to create both tensile and compressive stress films on NFET and PFET, respectively. Accordingly, relaxation of compressive film for NFET in the densely packed array field-effect transistors (FETs) is desirable to improve static random-access memory (SRAM) yield. In existing approaches, heavy ion implantation of Ge/Xe is used after a litho step. However, this can adversely impact film quality and raise reliability concerns.

### SUMMARY OF THE INVENTION

In one aspect of the present invention, a technique for a single liner process to achieve dual stress is provided. An exemplary method for imparting a dual stress property in a stress liner layer of a semiconductor device can include steps of depositing a metal layer over a compressive stress liner layer, applying a masking agent to a portion of the metal layer to produce a masked and unmasked region of the metal layer, etching the unmasked region of the metal layer to remove the metal layer in the unmasked region to thereby expose a corresponding portion of the compressive stress liner layer, removing the mask to expose the metal layer from the masked region, and irradiating the compressive stress liner layer to impart a tensile stress property to the exposed portion of the compressive stress liner layer.

In another aspect of the present invention, a method for imparting a dual stress property in a stress liner layer of a semiconductor device can include steps of depositing a metal layer over a compressive stress liner layer, applying a masking agent to a portion of the metal layer to produce a masked and unmasked region of the metal layer, etching the unmasked region of the metal layer to remove the metal layer in the unmasked region to thereby expose a corresponding portion of the compressive stress liner layer, removing the mask to expose the metal layer from the masked region, and irradiating the compressive stress liner layer to impart a neutral stress property to the exposed portion of the compressive stress liner layer.

In yet another aspect of the present invention, a method for imparting a dual stress property in a stress liner layer of a semiconductor device can include steps of depositing a metal layer over a neutral stress liner layer, applying a masking agent to a portion of the metal layer to produce a masked and unmasked region of the metal layer, etching the unmasked region of the metal layer to remove the metal layer in the unmasked region to thereby expose a corresponding portion of the neutral stress liner layer, removing the mask to expose the metal layer from the masked region, and irradiating the neutral stress liner layer to impart a tensile stress property to the exposed portion of the neutral stress liner layer.

This and other objects, features and advantages of the present invention will become apparent from the following detailed description of illustrative embodiments thereof, which is to be read in connection with the accompanying drawings.

### BRIEF DESCRIPTION OF THE DRAWINGS

FIG. 1 is a diagram illustrating the step of starting with a CMOS flow after silicide formation, according to an embodiment of the present invention;

FIG. 2 is a diagram illustrating the step of depositing a compressive liner on NFET and PFET, according to an embodiment of the present invention;

FIG. 3 is a diagram illustrating the step of depositing a metal layer, according to an embodiment of the present invention;

FIG. 4 is a diagram illustrating the step of performing a pattern photoresist to expose the NFET active region, according to an embodiment of the present invention;

FIG. 5 is a diagram illustrating the step of reactive-ion etching (RIE) the exposed area and stripping the photoresist, according to an embodiment of the present invention;

FIG. 6 is a diagram illustrating the step of applying ultra-violet (UV) light, according to an embodiment of the present invention;

FIG. 7 is a diagram illustrating the step of removing the TiN layer, according to an embodiment of the present invention;

FIG. 8 is a chart illustrating multiple possible applications, according to an embodiment of the present invention;

FIG. 9 is a flow diagram illustrating techniques for imparting a dual stress property in a stress liner layer of a semiconductor device, according to an embodiment of the present invention;

FIG. 10 is a flow diagram illustrating techniques for imparting a dual stress property in a stress liner layer of a semiconductor device, according to an embodiment of the present invention; and

FIG. 11 is a flow diagram illustrating techniques for imparting a dual stress property in a stress liner layer of a semiconductor device, according to an embodiment of the present invention.

### DETAILED DESCRIPTION OF EMBODIMENTS

As described herein, an aspect of the present invention includes a single stress liner process to achieve dual stress for a field-effect transistor (FET) device. In one embodiments, a neutral liner or a compressive stress liner (with, for example, a dielectric constant of ˜7 and 100 megapascals MPa of stress) can be used to achieve a dual stress effect using ultra-violet (UV) light in conjunction with the techniques detailed herein.

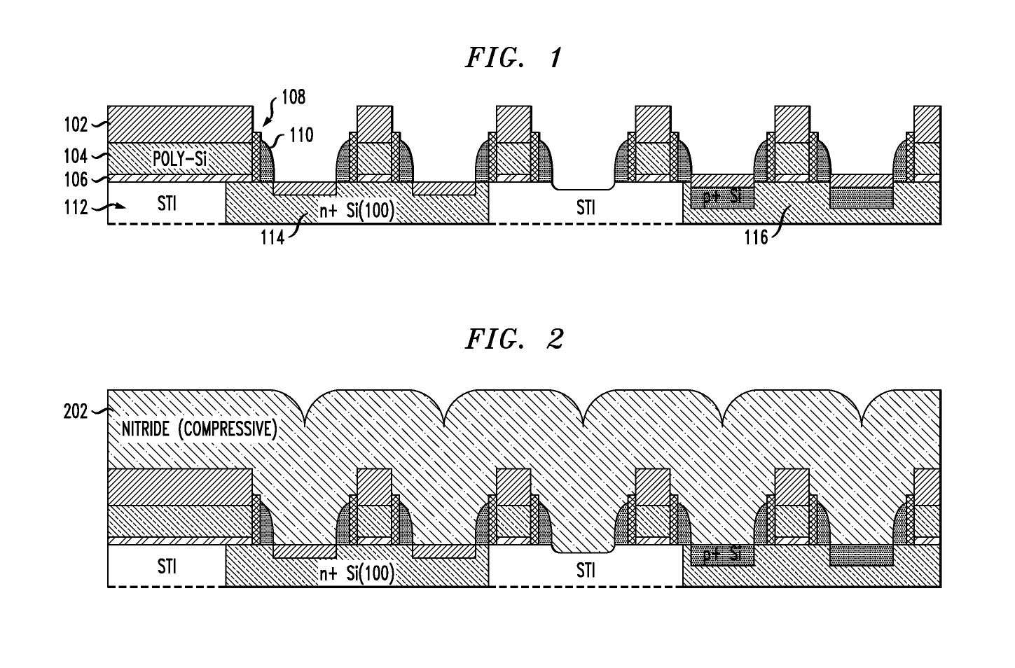

A preferred embodiment of the invention will be detailed in the progression of steps depicted in FIG. 1 through FIG. 7.

FIG. 1 is a diagram illustrating the step of starting with a CMOS flow after silicide formation, according to an embodiment of the present invention. By way of illustration, FIG. 1 depicts a polysilicon contact (PC) hardmask 102 (which can be SiO₂, SiN and etc.), a poly-silicon gate 104, a high-k metal gate stack 106, a first spacer 108, a second spacer 110, a shallow trench isolation (STI) 112, a p-type silicon substrate 114 and a n-type silicon substrate 116. By way of description, a PC hardmask is a layer of insulator on top of the gate for the purpose of protection. The components identified in FIG. 1 are also present in FIGS. 2-7, with the numerical labels detailed here being inferred thereon.

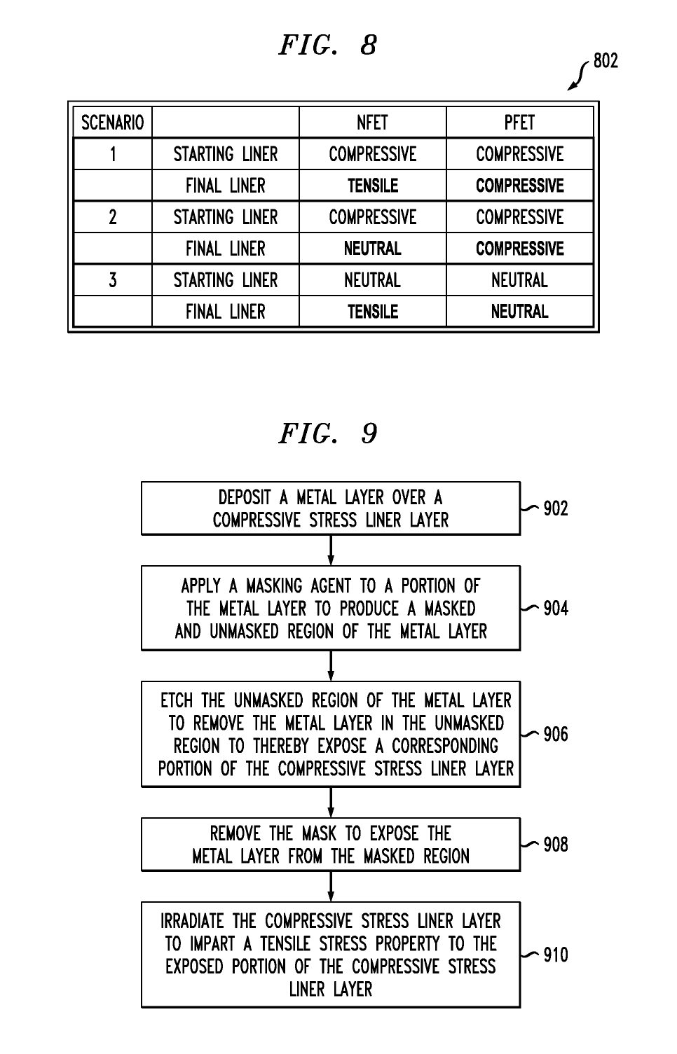

FIG. 2 is a diagram illustrating the step of depositing a compressive liner layer 202 (a nitride layer, in this example embodiment) on NFET and PFET, according to an embodiment of the present invention. The embodiment depicted in FIG. 2 coincides with scenario 1 and scenario 2 identified in the chart in FIG. 8. It is noted, additionally, that in another embodiment of the invention (such as would coincide with scenario 3 in the FIG. 8 chart), the step depicted herein FIG. 2 can be modified to deposit a neutral liner layer.

By way of example, an aspect of the invention includes depositing the compressive (or neutral) liner layer of a thickness of approximately 50-80 nanometers, but it should also be appreciated that any appropriate amount can be used so as to fill the nitride between the gates while maintaining a desired stress level.

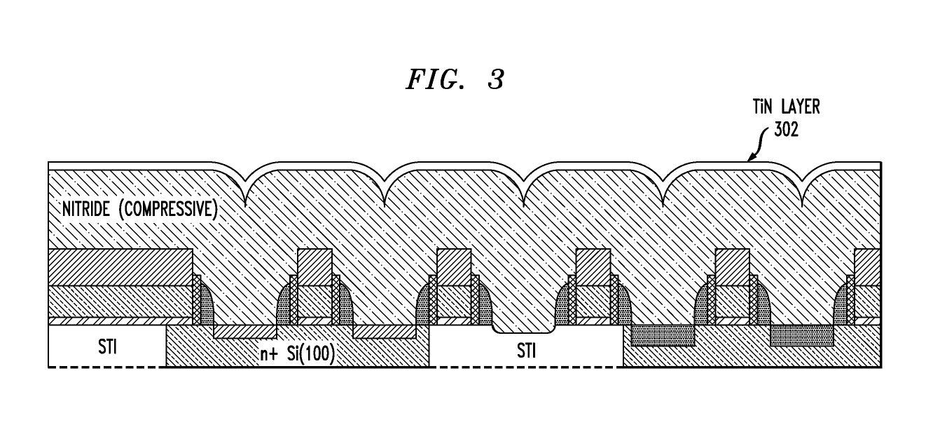

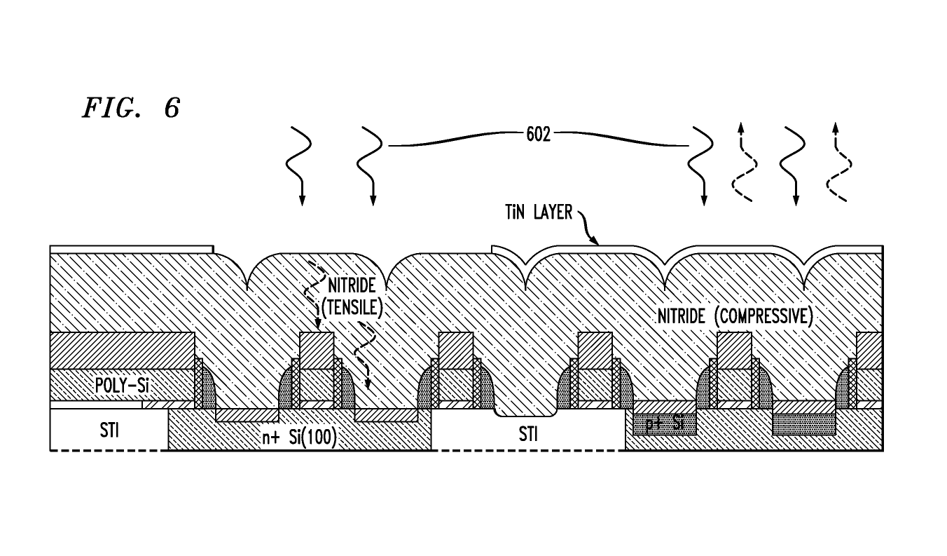

FIG. 3 is a diagram illustrating the step of depositing a metal layer 302 (a TiN layer, in this example embodiment), according to an embodiment of the present invention. As further described herein, the metal (TiN) layer will be used as a mask for PFET in the embodiment of the invention depicted in FIGS. 1-7. This metal layer will be used to reflect UV light so that the UV curing step (see, for example, FIG. 6) can be carried out selectively. By way of example, an aspect of the invention includes depositing the metal layer of a thickness of 5-6 nanometers, but it should also be appreciated that any appropriate amount can be used so as to block UV light while not creating subsequent etching problems.

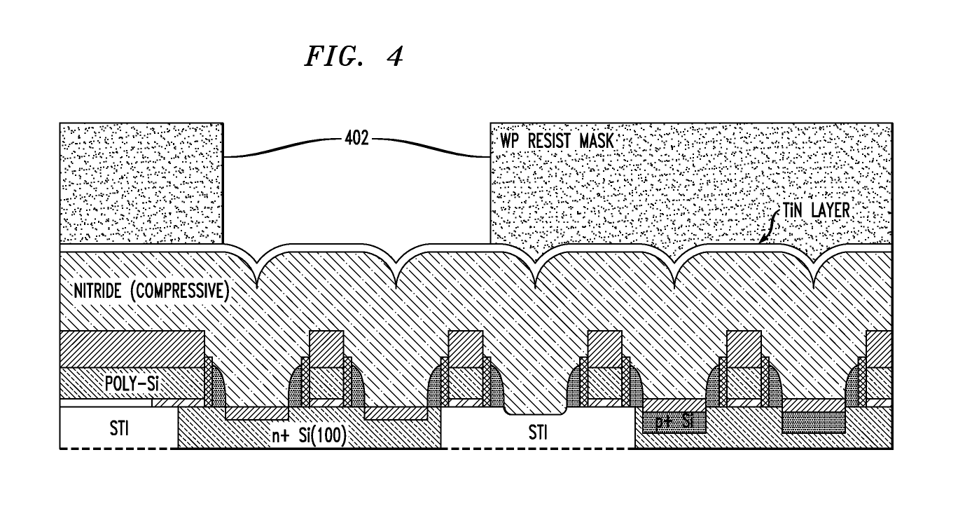

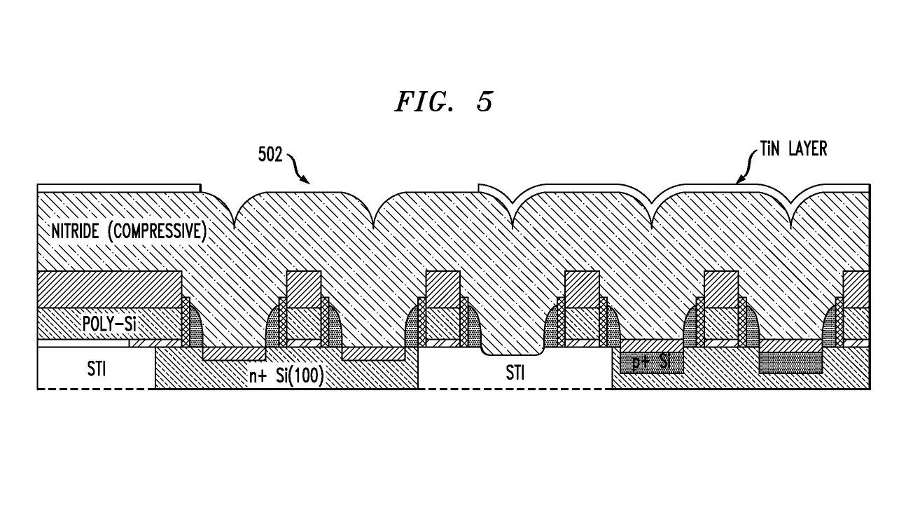

FIG. 4 is a diagram illustrating the step of performing a pattern photoresist to expose the NFET active region, according to an embodiment of the present invention. By way of illustration, FIG. 4 depicts the application of a resist mask 402 over the metal layer covering the PFET region(s).

FIG. 5 is a diagram illustrating the step of reactive-ion etching (RIE) the exposed area 502 and stripping the photoresist, according to an embodiment of the present invention. By way of illustration, FIG. 5 depicts that the metal layer remains on the PFET region(s) that were covered by the resist mask (as seen in FIG. 4) and the metal layer from the exposed NFET region has been removed via RIE.

FIG. 6 is a diagram illustrating the step of applying ultra-violet (UV) light 602, according to an embodiment of the present invention. By way of illustration, FIG. 6 depicts the application of UV light 602 to both the NFET and PFET regions. As a result, the UV light converts the (nitride) liner layer on NFET from compressive to tensile (or, in another example embodiment, neutral) for a dual stress liner effect. PFET is not affected as the UV light, as the UV light is reflected by the metal (for example, TiN) layer that remains. By way merely of example, in one embodiment of the invention, the UV light wavelength can range from approximately 172 nanometers (nm) to approximately 400 nm. Also, the UV light wavelength and intensity can be selected based on the tensile stress that is to be achieved.

The use of a single stress liner process to achieve a dual stress liner (DSL) effect through application of UV light eliminates any degradation to silicide resistance and issues associated with boundary.

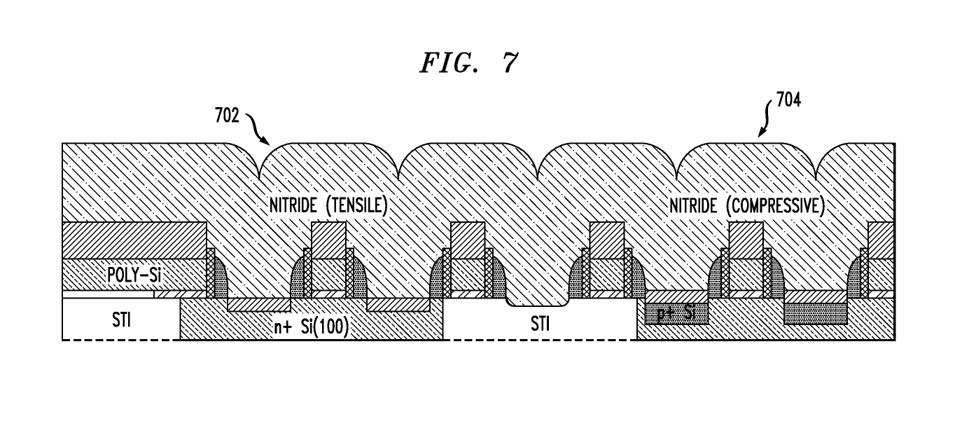

FIG. 7 is a diagram illustrating the step of removing the TiN layer, according to an embodiment of the present invention. By way of illustration, FIG. 7 depicts the resulting tensile liner layer 702 on NFET and resulting compressive liner layer 704 on PFET. The final structure depicted in FIG. 7 is arrived at after removal of the remaining portions of the metal (TiN) layer. By way of example, the remaining portions of the metal (TiN) layer can be removed via a standard chemical solution, as would be appreciated by one skilled in the art.

In one embodiment of the invention, the final structure is a continuous film over the entire wafer without any boundary. However, the composition of Si—N—H in the film on NFET and PFET regions will be distinctively different, specifically for H concentration and Si—H/N—H bond ratios.

FIG. 8 is a chart 802 illustrating multiple possible applications, according to an embodiment of the present invention. Scenario 1 is for the case that both the tensile and compressive stress are required from nitride liners for NFET and PFET simultaneously. This is a traditional DSL. Scenario 2 is for the case that only the compressive stress is required for PFET, while it is not required for NFET. Because the stress sensitivity of NFET is usually less than PFET, this is essentially trading NFET mobility for process simplicity. Additionally, as noted above, scenario 1 and scenario 2 coincide with the example embodiment illustrated in FIG. 2 where a compressive liner layer is initially deposited.

As also detailed in FIG. 8, scenario 3 is for the case where only the tensile liner stress is required for NFET. This can be implemented, for example, when the compressive stress from eSiGe is sufficient for PFET. The conversion from neutral to tensile stress by UV has been reported in literature. It is noted, additionally, that the embodiment of the invention such as outlined in scenario 3, represents a modification of the step depicted FIG. 2 whereby a neutral liner layer would be initially deposited instead of a compressive liner layer.

Additionally, for these three difference schemes, to make a film (for example, a SiN film) more tensile, aspects of the invention can include the following techniques. One aspect can include modifying temperature during the UV cure. The higher the temperature, the more tensile stress (of the imparted property). Another aspect can include increasing the UV cure time. The longer the cure time, the higher the tensile stress (of the imparted property). Essentially, the less hydrogen in the (SiN) film, the higher the tensile stress.

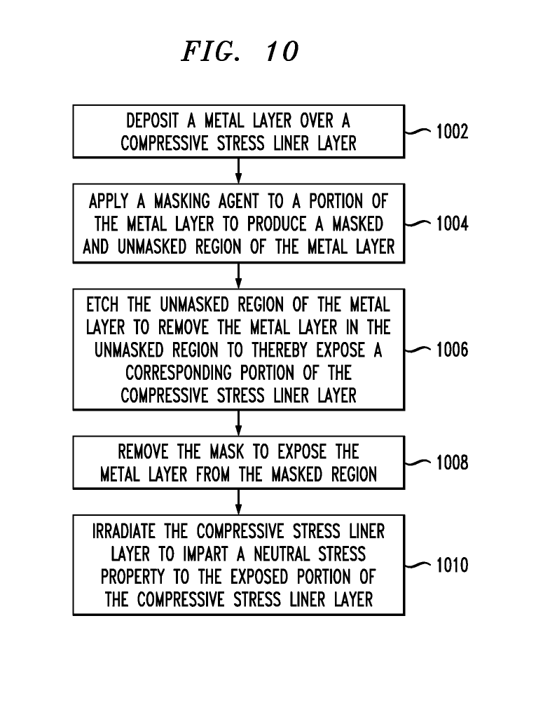

FIG. 9 is a flow diagram illustrating techniques for imparting a dual stress property in a stress liner layer of a semiconductor device (for example, a complementary metal-oxide-semiconductor (CMOS)), according to an embodiment of the present invention. One embodiment of the invention includes applying a compressive stress liner layer (for example, a nitride compressive stress liner layer) to a semiconductor device. Applying a compressive stress liner layer to a semiconductor device can include applying a compressive stress liner layer over silicided gates and source/drain (S/D) regions of the semiconductor device.

With respect to FIG. 9, Step 902 includes depositing a metal layer (for example, a TiN layer, a TaSiN layer, an HfN layer, a TaN layer, a W layer, etc.) over a compressive stress liner layer. Step 904 includes applying a masking agent to a portion of the metal layer to produce a masked and unmasked region of the metal layer. Masking a portion of the metal layer with a mask further includes patterning a photoresist to expose the unmasked region of the metal layer.

Step 906 includes etching (for example, a reactive-ion etching) the unmasked region of the metal layer to remove the metal layer in the unmasked region to thereby expose a corresponding portion of the compressive stress liner layer. Step 908 includes removing the mask to expose the metal layer from the masked region.

Step 910 includes irradiating the compressive stress liner layer to impart a tensile stress property to the exposed portion of the compressive stress liner layer. Irradiating the compressive stress liner layer includes applying ultra-violet light to the compressive stress liner layer.

The techniques depicted in FIG. 9 can additionally include removing the masked region of the metal layer.

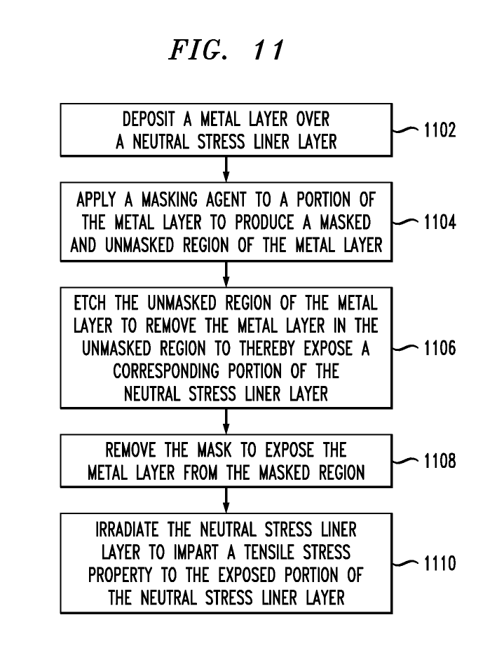

FIG. 10 is a flow diagram illustrating techniques for imparting a dual stress property in a stress liner layer of a semiconductor device (for example, a CMOS), according to an embodiment of the present invention. One embodiment of the invention includes applying a compressive stress liner layer (for example, a nitride compressive stress liner layer) to a semiconductor device. Applying a compressive stress liner layer to a semiconductor device can include applying a compressive stress liner layer over silicided gates and source/drain (S/D) regions of the semiconductor device.

With respect to FIG. 10, step 1002 includes depositing a metal layer (for example, a TiN layer, a TaSiN layer, an MN layer, a TaN layer, a W layer, etc.) over a compressive stress liner layer.

Step 1004 includes applying a masking agent to a portion of the metal layer to produce a masked and unmasked region of the metal layer. Masking a portion of the metal layer with a mask additionally includes patterning a photoresist to expose the unmasked region of the metal layer. Step 1006 includes etching (for example, a reactive-ion etching) the unmasked region of the metal layer to remove the metal layer in the unmasked region to thereby expose a corresponding portion of the compressive stress liner layer. Step 1008 includes removing the mask to expose the metal layer from the masked region.

Step 1010 includes irradiating the compressive stress liner layer to impart a neutral stress property to the exposed portion of the compressive stress liner layer. Irradiating the compressive stress liner layer includes applying ultra-violet light to the compressive stress liner layer.

The techniques depicted in FIG. 10 can additionally include removing the masked region of the metal layer.

FIG. 11 is a flow diagram illustrating techniques for imparting a dual stress property in a stress liner layer of a semiconductor device (for example, a CMOS), according to an embodiment of the present invention. One embodiment of the invention includes applying a neutral stress liner layer (for example, a nitride neutral stress liner layer) to a semiconductor device. Applying a neutral stress liner layer to a semiconductor device can include applying a neutral stress liner layer over silicided gates and source/drain (S/D) regions of the semiconductor device.

With respect to FIG. 11, step 1102 includes depositing a metal layer (for example, a TiN layer, a TaSiN layer, an HfN layer, a TaN layer, a W layer, etc.) over a neutral stress liner layer depositing a metal layer over the neutral stress liner layer.

Step 1104 includes applying a masking agent to a portion of the metal layer to produce a masked and unmasked region of the metal layer. Masking a portion of the metal layer with a mask can also include patterning a photoresist to expose the unmasked region of the metal layer. Step 1106 includes etching (for example, a reactive-ion etching) the unmasked region of the metal layer to remove the metal layer in the unmasked region to thereby expose a corresponding portion of the neutral stress liner layer. Step 1108 includes removing the mask to expose the metal layer from the masked region.

Step 1110 includes irradiating the neutral stress liner layer to impart a tensile stress property to the exposed portion of the neutral stress liner layer. Irradiating the neutral stress liner layer includes applying ultra-violet light to the neutral stress liner layer.

The techniques depicted in FIG. 11 can additionally include removing the masked region of the metal layer.

The method as described above is used in the fabrication of integrated circuit chips.

Although illustrative embodiments of the present invention have been described herein with reference to the accompanying drawings, it is to be understood that the invention is not limited to those precise embodiments, and that various other changes and modifications may be made by one skilled in the art without departing from the scope or spirit of the invention.

What is claimed is:

1. A method for imparting a dual stress property in a stress liner layer of a semiconductor device, comprising:
depositing a metal layer over a compressive stress liner layer;
applying a masking agent to a portion of the metal layer to produce a masked and unmasked region of the metal layer;
etching the unmasked region of the metal layer to remove the metal layer in the unmasked region to thereby expose a corresponding portion of the compressive stress liner layer;
removing the mask to expose the metal layer from the masked region; and
irradiating the compressive stress liner layer to impart a tensile stress property to the exposed portion of the compressive stress liner layer.

2. The method of claim 1, wherein irradiating the compressive stress liner layer comprises applying ultra-violet light to the compressive stress liner layer.

3. The method of claim 1, further comprising:
removing the masked region of the metal layer.

4. The method of claim 1, wherein the stress liner layer is a nitride compressive stress liner layer.

5. The method of claim 1, wherein the metal layer comprises one of a TiN layer, a TaSiN layer, an HfN layer, a TaN layer, and a W layer.

6. The method of claim 1, further comprising:
patterning a photoresist to expose the unmasked region of the metal layer.

7. The method of claim 1, wherein the step of etching is a reactive-ion etching.

8. A method for imparting a dual stress property in a stress liner layer of a semiconductor device, comprising:
depositing a metal layer over a compressive stress liner layer;
applying a masking agent to a portion of the metal layer to produce a masked and unmasked region of the metal layer;
etching the unmasked region of the metal layer to remove the metal layer in the unmasked region to thereby expose a corresponding portion of the compressive stress liner layer;
removing the mask to expose the metal layer from the masked region; and
irradiating the compressive stress liner layer to impart a neutral stress property to the exposed portion of the compressive stress liner layer.

9. The method of claim 8, further comprising:
removing the masked region of the metal layer.

10. The method of claim 8, wherein the stress liner layer is a nitride compressive stress liner layer.

11. The method of claim 8, wherein irradiating the compressive stress liner layer comprises applying ultra-violet light to the compressive stress liner layer.

12. The method of claim 8, wherein the metal layer comprises one of a TiN layer, a TaSiN layer, an HfN layer, a TaN layer, and a W layer.

13. The method of claim 8, further comprising:
patterning a photoresist to expose the unmasked region of the metal layer.

14. The method of claim 8, wherein the step of etching is a reactive-ion etching.

15. A method for imparting a dual stress property in a stress liner layer of a semiconductor device, comprising:
depositing a metal layer over a neutral stress liner layer;
applying a masking agent to a portion of the metal layer to produce a masked and unmasked region of the metal layer;
etching the unmasked region of the metal layer to remove the metal layer in the unmasked region to thereby expose a corresponding portion of the neutral stress liner layer;
removing the mask to expose the metal layer from the masked region; and
irradiating the neutral stress liner layer to impart a tensile stress property to the exposed portion of the neutral stress liner layer.

16. The method of claim 15, wherein irradiating the neutral stress liner layer comprises applying ultra-violet light to the neutral stress liner layer.

17. The method of claim 15, wherein the stress liner layer is a nitride neutral stress liner layer.

18. The method of claim 15, wherein the metal layer comprises one of a TiN layer, a TaSiN layer, an HfN layer, a TaN layer, and a W layer.

19. The method of claim 15, further comprising:
patterning a photoresist to expose the unmasked region of the metal layer.

20. The method of claim 15, wherein the step of etching is a reactive-ion etching.
